(19) United States
(12) Patent Application Publication
(10) Pub. No.: US 2023/0389305 A1
(43) Pub. Date: Nov. 30, 2023

(54) SEMICONDUCTOR MEMORY DEVICE

(71) Applicant: SK hynix Inc., Gyeonggi-do (KR)

(72) Inventors: Kyu Jin CHOI, Gyeonggi-do (KR); Hae Ri KIM, Gyeonggi-do (KR); Kyu Chan SHIM, Gyeonggi-do (KR)

(21) Appl. No.: 17/989,937

(22) Filed: Nov. 18, 2022

(30) Foreign Application Priority Data
May 31, 2022 (KR) 10-2022-0066702

(51) Int. Cl. H01L 29/76; H01L 23/528

(52) U.S. Cl. CPC H10B 41/27; H10B 41/10; H01L 23/5283

(57) ABSTRACT

A semiconductor memory device includes: a first stack structure and a second stack structure on a semiconductor substrate; a first vertical structure having a side all in contact with the first stack structure, the first vertical structure including a first memory layer and a first channel pattern; a second vertical structure having a sidewall in contact with the second stack structure, the second vertical structure including a second memory layer and a second channel pattern; a first bit line contact structure on the first vertical structure; and a first bit line overlapping with the first bit line contact structure. Each of the first stack structure and the second stack structure includes conductive layers stacked on the semiconductor substrate to be spaced apart from each other. The first bit line contact structure has a shape which is widened toward the first bit line.

### CROSS-REFERENCE TO RELATED APPLICATION

The present application claims priority under 35 U.S.C, § 119(a) to Korean patent application number 10-2022-0066702, filed on May 31, 2022, in the Korean Intellectual Property Office, the entire disclosure of which is incorporated herein by reference.

### BACKGROUND

### Field of Invention

The present disclosure generally relates to a semiconductor memory device, and more particularly, to a three-dimensional semiconductor memory device.

### Description of Related Art

A nonvolatile memory device is a memory device in which stored data is retained even when the supply of power is interrupted. As the improvement of the degree of integration of two-dimensional nonvolatile memory devices in which memory cells are formed in the form of a single layer over a substrate reaches a limit, there has recently been considered a three-dimensional nonvolatile memory device in which memory cells are stacked vertically over a substrate.

The three-dimensional nonvolatile memory device includes insulating layers and gate electrodes, which are alternately stacked, and channel layers penetrating the insulating layers and the gate electrodes, and memory cells are stacked along the channel layers, Various structures and various manufacturing methods have been developed so as to improve the operational reliability of such a nonvolatile merraory device having a three-dimensional structure.

### SUMMARY

Embodiments provide a semiconductor memory device capable of improving the degree of integration of memory cells.

In accordance with one aspect of the present disclosure, there is provided a semiconductor memory device including: a first stack structure and a second stack structure on a semiconductor substrate; a first vertical structure having a sidewall in contact with the first stack structure, the first vertical structure including a first memory layer and a first channel pattern; a second vertical structure having a sidewall in contact with the second stack structure, the second vertical structure including a second memory layer and a second channel pattern; a first bit line contact structure on the first vertical structure; and a first bit line overlapping with the first bit line contact structure, wherein each of the first stack structure and the second stack structure includes conductive layers stacked on the semiconductor substrate to be spaced apart from each other, and wherein the first bit line contact structure has a shape which is widened toward the first bit line.

In accordance with another aspect of the present disclosure, there is provided a semiconductor memory device including: a first stack structure and a second stack structure on a semiconductor substrate; a first vertical structure having a sidewall in contact with the first stack structure, the first vertical structure including a first memory layer and a first channel pattern; a second vertical structure having a sidewall in contact with the first stack structure, the second vertical structure including a second memory layer and a second channel pattern; a third vertical structure having a sideman in contact with the second stack structure, the third vertical structure including a third memory layer and a third channel pattern; a fourth vertical structure a sidewall in contact with the second stack structure, the fourth vertical structure including a fourth memory layer and a fourth channel pattern; a first bit line contact structure on the first vertical structure; and a first bit line overlapping with the first bit line contact structure, wherein each of the first stack structure and the second stack structure includes conductive layers stacked on the semiconductor substrate to be spaced apart from each other, and wherein the first bit line contact structure has a shape which is widened toward the first bit line.

In accordance with another aspect of the present disclosure, there is provided a semiconductor memory device comprising: a first stack structure and a second stack structure on a semiconductor substrate; a first vertical structure having a sidewall in contact with the first stack structure, the first vertical structure including a first memory layer and a first channel pattern extending vertically away from the semiconductor substrate; a second vertical structure having a sidewall in contact with the second stack structure, the second vertical structure including a second memory layer and a second channel pattern extending vertically away from the semiconductor substrate; a bit line contact structure on the first vertical structure; and a bit line overlapping with the bit line contact structure, wherein the first channel pattern is isolated into first separate channel patterns by vertically extending isolation layers disposed against the sideman of the first vertical structure, wherein the second channel pattern is isolated into second separate channel patterns by vertically extending isolation layers disposed against the sidewall of the second vertical structure, and wherein the bit line contact structure contacts one of the first separate channel patterns.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure wall convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present.

Like reference numerals refer to like elements throughout,

FIG. 1 is a perspective view of a semiconductor memory device in accordance with one embodiment of the present disclosure.

FIGS. 2A and 23 are plan views illustrating a layout of a semiconductor memory device in accordance with another embodiment of the present disclosure,

FIGS. 3A and 3B are plan views illustrating a layout of a semiconductor memory device in accordance with still another embodiment of the present disclosure,

FIG. 4 is a view illustrating a cross-section of a vertical structure in accordance with yet another embodiment of the present disclosure.

FIGS. 5A and 5B are sectional views of a semiconductor memory device taken along lines A-A′ and B-B′ shown in FIG. 33.

FIG. 6 is a sectional view of a semiconductor memory device taken along the line A-A′ shown in FIG. 3B,

FIG. 7 is a plan view illustrating a layout of a semiconductor memory device in accordance with one embodiment of the present disclosure.

FIGS. 8A to 8C are sectional views of a semiconductor memory device taken along lines C-C′, D-D′, and E-E shown in FIG. 7.

FIGS. 9A and 9B are plan views illustrating a layout of a semiconductor memory device in accordance with another embodiment of the present disclosure.

FIG. 10 is a view illustrating a cross-section of a vertical structure in accordance with still another embodiment of the present disclosure.

FIGS. 11A and 11B are sectional views of a semiconductor memory device taken along lines F-F′ and G-G′ shown in FIG. 9B.

FIG. 12 is a block diagram illustrating a configuration of a memory system in accordance with yet another embodiment of the present disclosure.

FIG. 13 is a block diagram illustrating a configuration of a computing system in accordance with another embodiment of the present disclosure.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Hereinafter, it will be understood that, although the terms “first,” “second,” etc. may be used herein to describe various elements, these elements should not be limited by these terms. These terms are only used to distinguish one element from another element, and the order or number of components is not limited by the terms.

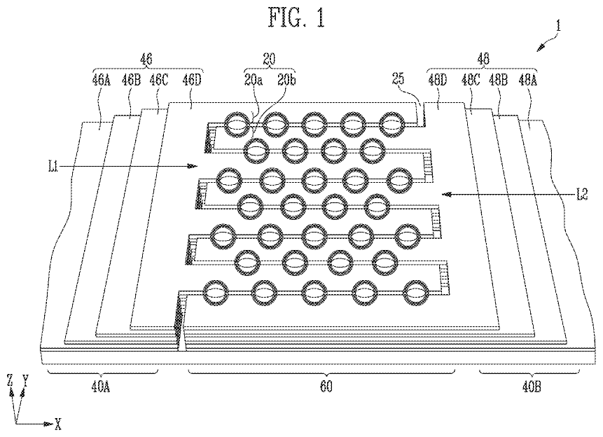

FIG. 1 is a perspective view of a semiconductor memory device in accordance with one embodiment of the present disclosure.

Referring to FIG. 1, the semiconductor memory device 1 may include a cell region 60, a first contact region 40A, and a second contact region 40B. The first contact region 40A and the second contact region 40B may be disposed at both sides of the cell region 60.

The semiconductor memory device 1 may include a first stack structure 46 and a second stack structure 48. The first stack structure 48 may extend to the first contact region 40A from the cell region 60 of the semiconductor memory device 1. The second stack structure 48 may extend to the second contact region 40B from the cell region 60 of the semiconductor memory device 1. Each of the first stack structure 46 and the second stack structure 48 may have a stepped shape in a contact region 40A or 40B corresponding thereto. The first stack structure 46 and the second stack structure 48 may be isolated from each other by a trench 25. An isolation insulating layer may be formed inside the trench 25, The semiconductor memory device 1 may include a plurality of vertical structures 20 penetrating the first stack structure 46 and the second stack structure 48 in the cell region 60. Each vertical structure may include a first vertical structure 20a and a second vertical structure 20b. The first vertical structure 20a and the second vertical structure 20b may be disposed facing each other.

The first stack structure 46 may include a plurality of first conductive layers 46A, 46B, 46C, and 46D stacked to be spaced apart from each other in a Z direction over a semiconductor substrate. The plurality of first conductive layers 46A, 468, 46C, and 46D may be in contact with a side portion of the first vertical structure 20a. The second stack structure 48 may include a plurality of second conductive layers 48A, 48B, 48C, and 48D spaced apart from each other over the semiconductor substrate. The plurality of second conductive layers 48A, 48B, 48C, and 48D may be in contact with a side portion of the second vertical stack structure 20b. The present disclosure is not limited to numbers of stack structures and conductive layers, which are shown in the drawing.

The first conductive layers 46A, 46B, 46C, and 46D of the first stack structure 46 may have a form in which the first conductive layers 46A, 46B, 46C, and 46D are engaged with the second conductive layers 48A, 48B, 48C, and 48D of the second stack structure 48 with the trench interposed therebetween. Hereinafter, the structure of the first stack structure 46 and the second stack structure 48, which are engaged with each other, will be described in more detail. The plurality of conductive layers 46A, 468, 46C, and 46D may form a stepped shape in the first contact area 40A. Each of the plurality of conductive layers 46A, 46B, 46C, and 46D may include a plurality of first line parts L1 extending to the cell region 60 from the first contact region 40A. The plurality of first line parts L1 may be spaced apart from each other in a Y direction.

The plurality of second conductive layers 48A, 48B, 48C, and 48D may have a stepped shape in the second contact region 40B. Each of the plurality of second conductive layers 48A, 488, 48C, and 48D may include a plurality of second line parts L2 extending to the cell region 60 from the second contact region 40B. The plurality of second line parts L2 may be spaced apart from each other in the Y direction.

The plurality of first line parts L1 and the plurality of second line parts L2 may be alternately disposed in the Y direction. Parts of trench may extend in an X direction between a first line part L1 and a second line part L2, which are adjacent to each other. Other parts of trench 25 may extend in the Y direction between the stepped shape of the first stack structure 46 and the second line part L2 of the second stack structure 48 and between the stepped shape of the second stack structure 48 and the first line part L1 of the first stack structure 46.

Each of the first stack structure 46 and the second stack structure 48 may include a cell stack structure and a select stack structure (to be described in more detail below), which are stacked in the Z direction. The cell stack structure may form a word line, and the select stack structure may form a drain select line. The select stack structure may have the same layout as the cell stack structure. The select stack structure may overlap with the cell stack structure, or be isolated into two or more sub-select stack structures by a line isolation structure to overlap with the cell stack structure.

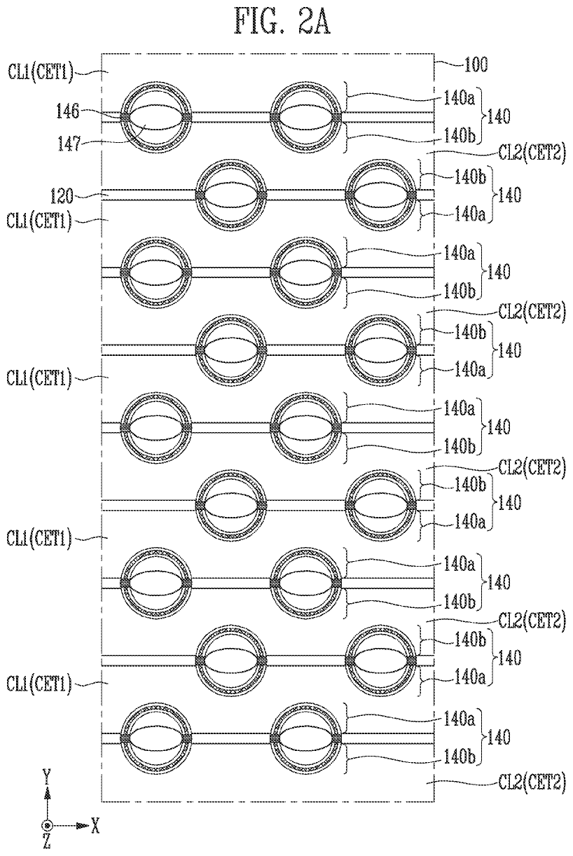

FIGS. 2A and 2B are plan views illustrating a layout of a semiconductor memory device in accordance with another embodiment of the present disclosure.

Referring to FIGS. 2A and 2B, the semiconductor memory device in accordance with this embodiment of the present disclosure may include first and second cell stack structures CET1 and CET2 and first and second select stack structures SET? and SET2. FIG. 2A is a plan view looking down on the top of the conductive layer stack and illustrates a layout of the first and second cell stack structures CET1 and CET2 in cell region 60 as shown in FIG. 1. FIG. 2B is a plan view looking down on the top of the bit lines and illustrates a layout of the first and second select stack structures SET1 and SET2 in cell region 60 as shown in FIG. 1. Hereinafter, a first direction X, a second direction Y, and a third direction Z may be defined as directions in which axes intersecting one another. In one embodiment, the first direction X, the second direction Y, and the third direction Z may be defined as X-axis, Y-axis, and Z-axis directions of an XYZ coordinate system as depicted on FIGS. 2A and 2B.

The first cell stack structure CET1 and the second cell stack structure CET2 may be isolated by an isolation insulating layer 120, similar to the first stack structure 46 and the second stack structure 48, which are described with reference to FIG. 1. The first cell stack structure CET1 may include a plurality of first cell line parts CL1 spaced apart from each other in the second direction Y, and the second cell stack structure CET2 may include a plurality of second cell line parts CL2. The plurality of first cell line parts CL1 may be alternately disposed with the plurality of second cell line parts CL2 in the second direction Y. The isolation insulating layer 120 may be disposed between a first cell line part CL1 and a second cell line part CL2, which are adjacent to each other in the second direction Y.

The first select stack structure SET1 may overlap with the first cell stack structure CET1, and include a plurality of first select line parts SL1, similar to the first cell stack structure CET1. The second select stack structure SET2 may overlap with the second cell stack structure CET2, and include a plurality of second select line parts SL2, similar to the second cell stack structure CET2. The isolation insulating layer 120 may extend between a first select line part SL1 and a second select line part SL2, which are adjacent to each other, and isolate the first select stack structure SET1 and the second select stack structure SET from each other.

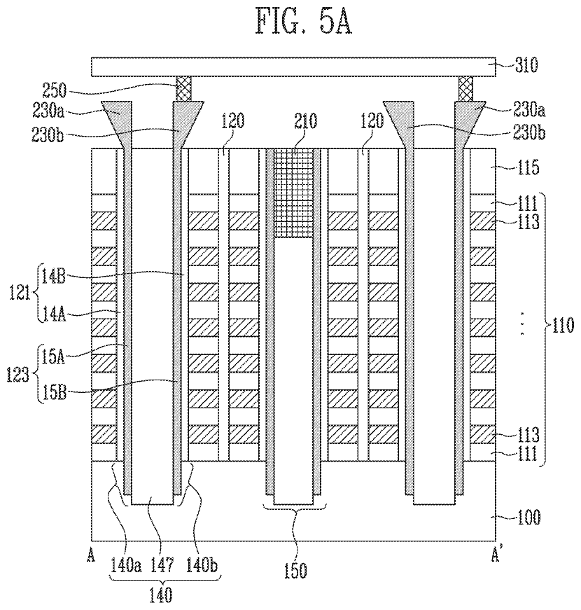

A line part of each of the first and second cell stack structures CET1 and CET2 and the first and second select stack structures SET1 and SET2 may extend in the first direction X and the second direction Y. Each of the first and second cell stack structures CET1 and CET2 and the first and second select stack structures SET1 and SET2 may include interlayer insulating layers and conductive layers, which are stacked in the third direction Z. A stacked structure of the interlayer insulating layers and the conductive layers will be described later with reference to FIG. 5A.

Conductive layers of each of the first and second cell stack structures CET1 and CET2 may constitute a word line. Conductive layers of the first and second select stack structures SET1 and SET2 may constitute a drain select line.

The first and second cell stack structures CET1 and CET2 and the first and second select stack structures SET1 and SET2 may be penetrated by vertical structures 140. The vertical stack structures 140 may extend in the third direction Z. The vertical structures 140 may be arranged in zigzag. However, the present disclosure is not limited thereto. For example, the vertical structures 140 may be arranged in parallel in the first direction X and the second direction Y.

The isolation insulating layer 120 may extend in the first direction X and the third direction Z between the first cell stack structure CET1, and the second cell stack structure CET2.

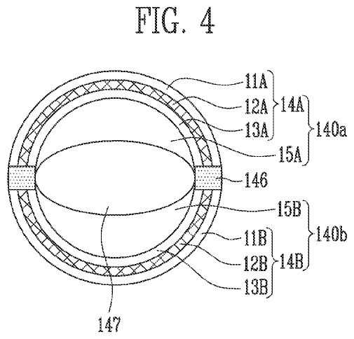

Each vertical structure 140 may include a first vertical structure 140a and a second vertical structure 140b. A side portion of the first vertical structure 140a may be in contact with a first cell line part CIA corresponding thereto and a first select line part SL1 corresponding thereto. A side portion of the second vertical structure 140b may be in contact with a second cell line part CL2 corresponding thereto and a second select line part SL2 corresponding thereto. The first vertical structure 140a and the second vertical structure 140b may be isolated from each other by a first isolation structure 146 and a second isolation structure 147. A detailed structure of the vertical structure 140 will be described later with reference to FIG. 4.

The vertical structures 140 may be connected to bit lines 310 (as shown in FIGS. 2B and 5A), The bit lines 310 may be disposed to be spaced apart from the first and second select stack structures SET1 and SET2 in the third direction Z, and be disposed above the first and second select stack structures SET1 and SET2. The bit lines 310 may be arranged to be spaced apart from each other in the first direction X. The bit lines 310 may extend in the second direction Y.

The bit lines 310 may be electrically connected to the vertical structures 140 through bit line contact structures 230a and 230b. The bit lines 310 may include a conductive material. For example, the bit lines 310 may include tungsten, aluminum or copper.

The bit line contact structures 230a and 230b may include a first bit line contact structure 230a on the first vertical structure 140a and a second bit line contact structure 230b on the second vertical structure 140b. The bit lines 310 may include a first bit line 310A and a second bit line 310B, which overlap with a first vertical structure 140a and a second vertical structure 140b, which face each other. The first bit line 310A and the second bit line 310B may be spaced apart from each other in the third direction Z from the first bit line contact structure 230a and the second bit line contact structure 230b. Each of the first vertical structure 140a and the second vertical structure 140b may be connected to a bit line 310 corresponding thereto by an upper contact 250 (as depicted in FIGS. 2B and 5A). In one embodiment, the first vertical structure 140a may be connected to the first bit line 310A through an upper contact 250 disposed between the first bit line contact structure 230a and the first bit line 310A at an intersection portion of the first bit line contact structure 230a and the first bit line 310A, The second vertical structure 140b may be connected to the second bit line 310B through another upper contact 250 disposed between the second bit line contact structure 230b and the second bit line 310B at an intersection portion of the second bit line contact structure 230b and the second bit line 310B.

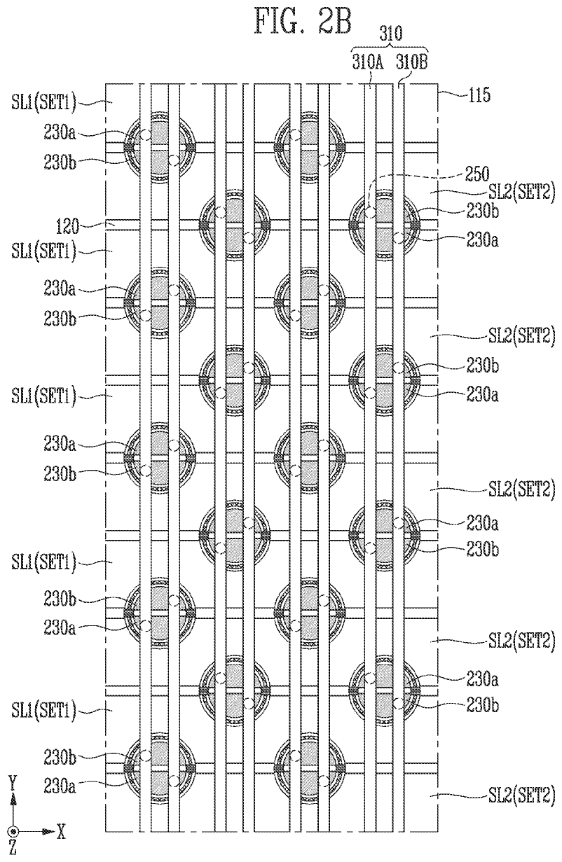

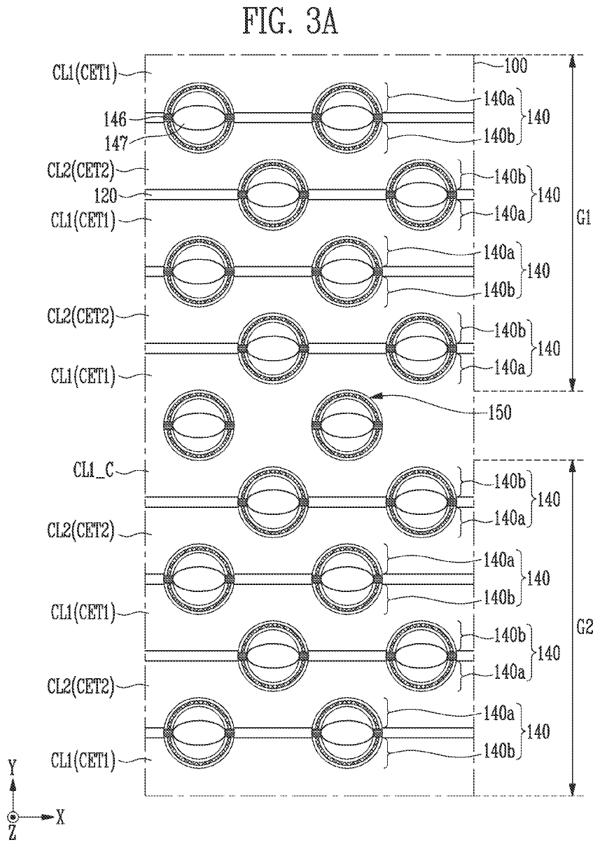

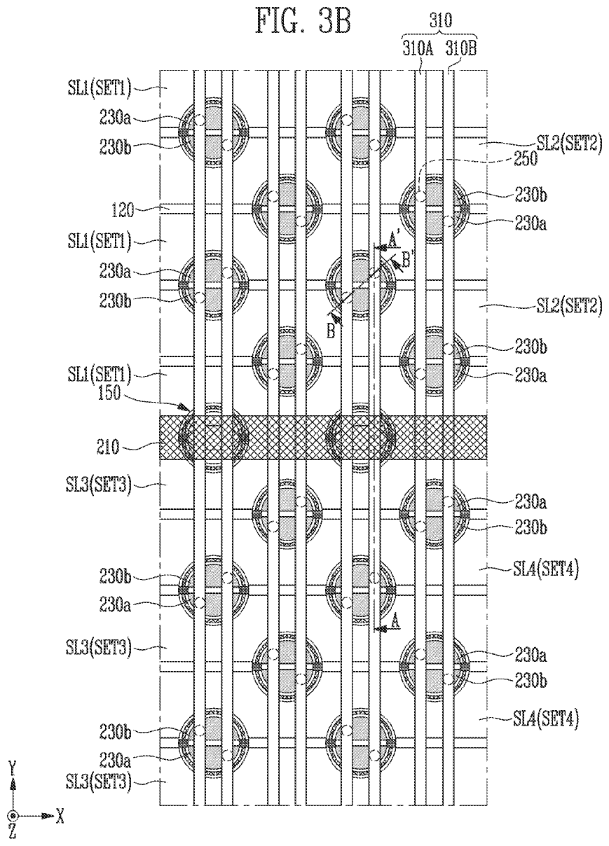

FIGS. 3A and 3B are plan views illustrating a layout of a semiconductor memory device in accordance with another embodiment of the present disclosure.

The semiconductor memory device in accordance with this embodiment of the present disclosure may be similar to the semiconductor memory device shown in FIGS. 2A and 2B, except portions described below.

Referring to FIGS. 3A and 3B, vertical structures 140 and dummy vertical structures 150 are depicted respectively in these drawings.

The dummy vertical structure 150 may penetrate any one of a plurality of first cell line parts CL1 of a first cell stack structure CET1 or any one of a plurality of second cell line parts CL2 of a second cell stack structure CET2, A cell line part surrounding the dummy vertical structure 150 may be formed with a wider width in the second direction Y as compared with the other cell line parts. In one embodiment, a first cell line part CL1_C disposed at the center among the plurality of first cell line parts CL1 of the first cell stack structure CET1 may be formed with a relatively wider width as compared with the other first cell line parts, and the dummy vertical structure 150 may penetrate the first cell line part CL1_C disposed at the center. The plurality of first cell line parts CL1 and the plurality of second cell line parts CL2 may be divided into a first group G1 and a second group G2 in the second direction Y with respect to the first cell line part CL1_C at the center.

First select line parts SL1 of a first select stack structure SET1 may overlap with some of the first cell line parts CL1 of the first cell stack structure CET1, which correspond to the first group G1, and second select line parts SL2 of a second select stack structure SET2 may overlap with some of the second select line parts CL2 of the second cell stack structure CET2, which correspond to the first group G1. Third select line parts SL3 of a third select stack structure SET3 may overlap with another some of the first cell line parts CL1 of the first cell stack structure CET1, which correspond to the second group G2, and fourth select line parts SL4 of a fourth select stack structure SET4 may overlap with another some of the second select line parts CL2 of the second cell stack structure CET1, which correspond to the second group G2. The select line parts SL1 to SL4 of the first to fourth select stack structures SET1 to SET4 may be connected to the contact region 40A or 40B shown in FIG. 1. For example, the first select line parts SL1 of the first select stack structure SET1 may be connected to each other in the contact region.

A portion of an isolation insulating layer 120 between a first cell line part CL1 and a second cell line part CL2 of the first group G1 may extend between a first select line part SL1 and a second select line part SL2, and another portion of an isolation insulating layer 120 between a first cell line part CL1 and a second cell line part CL2 of the second group G2 may extend between a third select line part SL3 and a fourth select line part SL4. The second select stack structure SET2 and the third select stack structure SET3 may be isolated from each other by a line isolation structure 210.

The line isolation structure 210 may penetrate upper ends of the dummy vertical structures 150. The line isolation structure 210 may extend in the first direction X and the third direction Z while traversing dummy vertical structures 150 adjacent to each other in the first direction X.

Each of the vertical stack structures 140 may include a first vertical structure 140a corresponding to the first cell line part CL1 and a second vertical stack structure 140b corresponding to the second cell line part CL2.

FIG. 4 is a view illustrating a cross-section of a vertical structure in accordance with another embodiment of the present disclosure.

Referring to FIG. 4, the vertical structure in accordance with this embodiment of the present disclosure may include channel layers 15A and 15B, memory layers 14A and 14B surrounding the channel layers 15A and 15B, a first isolation structure 146 isolating the memory layers 14A and 14B, and a second isolation structure 147 isolating the channel layers 15A and 15B. The channel layers 15A and 15B may have a cylindrical shape penetrating the first and second cell stack structures CET1 and CET2 and the first and second select stack structures SET1 and SET2, which are described with reference to FIGS. 2A and 2B. [0055] The memory layers 14A and 14B isolated by the first isolation structure 146 may be referred to as a first memory layer 14A and a second memory layer 146, The channel layers 15A and 156 isolated by the second isolation structure 147 may be referred to as a first channel pattern 15A and a second channel pattern 15B. The first isolation structure 146 and the second isolation structure 147 may be connected to each other. The first isolation structure 146 may be connected to the isolation insulating layer 120 described with reference to FIGS. 2A and 23. In one embodiment, one vertical structure may include two first isolation structures 146, and include a second isolation structure 147 as a long ellipse in contact with the first isolation structure 146. The shapes of the first isolation structure 146 and the second isolation structure 147 are not limited to those shown in the drawing. The first memory layer 14A and the first channel pattern 15A may constitute the first vertical structure id 140a shown in FIGS. 2A and 2B or the first vertical structure 140a shown in FIGS. 3A and 33. The second memory layer 143 and the second channel pattern 15B may constitute the second vertical structure 140b shown in FIGS. 2A and 213 or the second vertical structure 140h shown in FIGS. 3A and 3B. [0056] The memory layer 14A and 143 may include tunnel insulating layers 12A and 123, charge storage layers 12A and 123, and blocking insulating layers 11A and 11B, which are sequentially stacked on a surface of the channel layer 15A and 15B, The charge storage layers 12A and 123 may be formed of a material layer capable of storing data changed using Fowler-Nordheim tunneling, To this end, the charge storage layers 12A and 12B may be formed of various materials. For example, the charge storage layers 12A and 1213 may be formed as a nitride layer capable of trapping charges. However, the present disclosure is not limited thereto, and the charge storage layers 12A and 12B may include silicon, a phase change material, a nano dot, and the like. The blocking insulating layers 11A and 11B may include an oxide layer capable of blocking movement of charges. The blocking insulating layers 11A and 11B may be formed as a silicon oxide layer through which charges can tunnel,

FIGS. 5A and 5B are sectional views of a semiconductor memory device taken along lines A-A′ and B-B′ shown in FIG. 3B.

Referring to FIGS. 5A and 5B, the semiconductor memory device in accordance with this embodiment of the present disclosure may include a semiconductor substrate 100, a stack structure 110 on the semiconductor substrate 100, and a plurality of vertical structures 140 penetrating the stack structure 110, The semiconductor memory device may further include bit line contact structures 230a and 230b, a bit line 310, and an upper contact 250 connecting the bit line 310 and the bit line contact structures 230a and 230b to each other. Also, the semiconductor memory device may include a plurality of dummy vertical structures 150 penetrating the stack structure 110. The vertical structure 140 may include a first vertical structure 140a and a second vertical structure 140b, which are isolated from each other by a second isolation structure 147. A first cell string and a second cell string may be defined along the first vertical structure 140a and the second vertical structure 140b.

The stack structure 110 may include interlayer insulating layers 111 and conductive layers 113, which are alternately stacked. The conductive layers 113 may include a source select line, a word line, and a its drain select line. The semiconductor memory device may further include a line isolation structure 210 isolating the drain select line. The interlayer insulating layers 111 are used to insulate the stacked conductive layers 113 from each other, and may include an insulating material including oxide, nitride, and the like.

The conductive layers 113 may be spaced apart from each other in an extending direction of the conductive layers 113 by an isolation insulating layer 120.

The plurality of vertical structures 140 and the plurality of dummy vertical structures 150 may penetrate the stack structure 110 and an upper insulating layer 115 on the stack structure 110 along a stacking direction of the stack structure 110. Each of the plurality of vertical structures 140 and the plurality of dummy vertical structures 150 may include a channel layer 123 surrounded by a memory layer 121, and the second isolation structure 147 forming a central region of each of the vertical structures 140 and 150.

The channel layer 123 may be a vertical structure. The channel layer 123 may be used as a channel region of select transistors and memory cells, which belong to a cell string corresponding thereto. The channel layer 123 may be configured with silicon (Si), germanium (Ge), or a combination thereof. In one embodiment, the channel layer 123 may include undoped silicon, and may include a doping region including at least one of an n-type impurity and a p-type impurity.

The second isolation structure 147 may penetrate a portion of the semiconductor substrate 100. The channel layer 123 may be isolated into two or more channel patterns by the second isolation structure 147. In one embodiment, the channel layer 123 may be isolated into a first channel pattern 15A and a second channel pattern 15B by the second isolation structure 147. The memory layer 121 may be isolated by the first isolation structure 146 described with reference to FIG. 4 into a first memory layer 14A between the first channel pattern 15A and the stack structure 100 and a second memory layer 14B between the second channel pattern 15B and the stack structure 100.

Each of the first channel pattern 15A of the first vertical structure 140a and the second channel pattern 15B of the second vertical structure 140b may be connected to a bit line 310 corresponding thereto. The first channel layer 123 may extend to further protrude beyond the stack structure 110 and the upper insulating layer 115. A portion of the channel layer 123, which extends from the first channel pattern 15A and protrudes beyond the stack structure 110 and the upper insulating layer 115, may form a first bit line contact structure 230a, and another portion of the channel layer 123, which extends from the second channel pattern 15B and protrudes beyond the stack structure 110 and the upper insulating layer 115, may form a second bit line contact structure 230b. The first and second bit line contact structures 230a and 230b may be connected to bit lines 310 by upper contacts 250. The channel layer 123 may have a shape of which is widened toward the bit line 310. For example, the bit line contact structure 230a and 130b may have a trapezoidal shape on a section. Therefore, a top surface of each of the first and second bit line contact structures 230a and 230b may have an area wider than an area of a cross-section of each of the first and second channel layers 15A and 15B. Accordingly, an alignment margin can be increased when the upper contacts 250 are aligned on the first and second bit line contact structures 230a and 230b. Referring to FIG. 5B, a plurality of bit lines 310 may be disposed above one vertical structure 140. In one embodiment, when the channel layer 123 is isolated into the first channel pattern 15A and the second channel pattern 153 by the second isolation structure 147, two bit lines 310 may be disposed above one vertical structure 140. The channel patterns may be controlled by the bit lines 310, respectively.

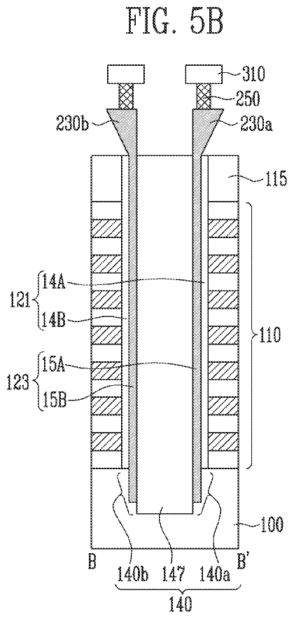

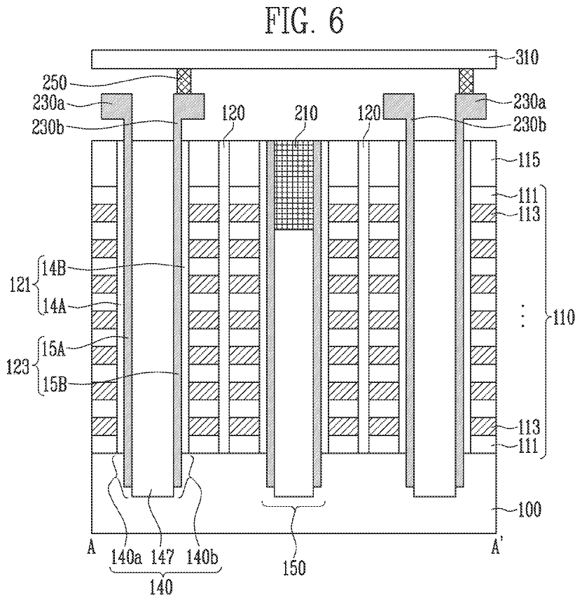

FIG. 6 is a sectional view of a semiconductor memory device taken along the line A-A′ shown in FIG. 3B, The semiconductor memory device in accordance with this embodiment of the present disclosure may be similar to the semiconductor memory device shown in FIG. 5A, except portions described below.

Referring to FIG. 6, in one embodiment, the bit line contact structure 230a and 230b may have a rectangular shape on a section. Therefore, the top surface of each of the first and second bit line contact structures 230a and 230b may have an area wider than the area of the cross-section of each of the first and second channel patterns 15A and 15B. Accordingly, an alignment margin can be increased when the upper contacts 250 are aligned on the first and second bit line contact structures 230a and 230b.

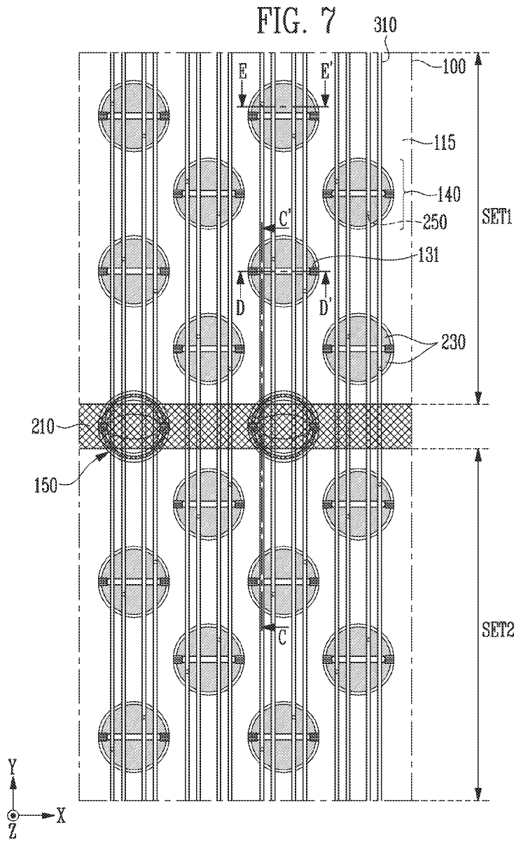

FIG. 7 is a plan view illustrating a layout of a semiconductor memory device in accordance with another embodiment of the present disclosure.

Referring to FIG. 7, the semiconductor memory device in accordance with this embodiment of the present disclosure may include first and second select stack structures SET1 and SET2. The conductive layers of the first and second select stack structures SET1 and SET2 may constitute a drain select line. The first and second select stack structures SET1 and SET2 may extend in the first direction X and the second direction Y, Each of the first and second select stack structures SET1 and SET2 may include interlayer insulating layers and conductive layers, which are stacked in the third direction Z.

The first and second select stack structures SET1 and SET2 may be penetrated by vertical structures 140. The vertical structures 140 may extend in the third direction Z, The vertical structures 140 may be arranged in zigzag. However, the present disclosure is not limited thereto. For example, the vertical structures 140 may be arranged in parallel in the first direction X and the second direction Y.

As described with reference to FIGS. 2A and 2B, in this embodiment of FIG. 7, each vertical structure 140 may include a first vertical structure 140a and a second vertical structure 140b, The first vertical structure 140a and the second vertical structure 140b may be isolated from each other by a first isolation structure 146 and a second isolation structure 147.

The vertical structures 140 may be connected to bit lines 310, The bit lines 310 may be disposed to be spaced apart from the first and second select stack structure SET1 and SET2 in the third direction Z, and be disposed on the first and second select stack structures SET1 and SET2, The bit lines 310 may be arranged to be spaced apart from each other in the first direction X. The bit lines 310 may extend in the second direction Y.

The bit lines 310 may be electrically connected to the vertical structures 140 through bit line contact structures 230. The bit lines 310 may include a conductive material. For example, the bit lines 310 may include tungsten, aluminum or copper.

The connection between the bit line contact structures 230 and the vertical structures 140 is similar to the connection between the bit line contact structures and the vertical structures in the semiconductor memory device shown in FIGS. 2A and 2B.

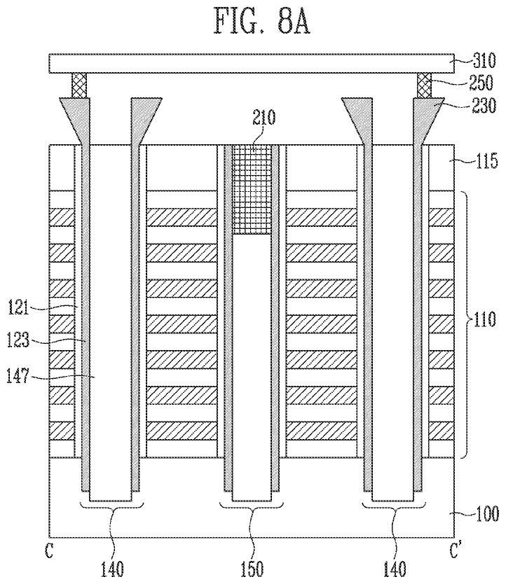

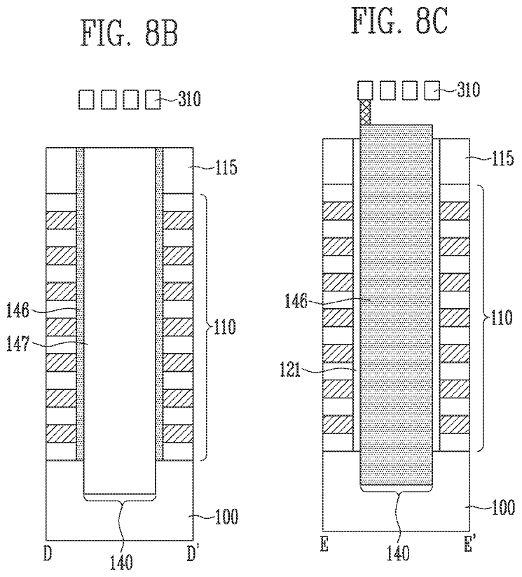

FIGS. 8A to 8C are sectional views of a semiconductor memory device taken along lines C-C′, D-D′, and E-E′ shown in FIG. 7.

The semiconductor memory device in accordance with this embodiment of the present disclosure may be similar to the semiconductor memory device shown in FIGS. 5A and 53, except portions described below.

Referring to FIGS. 8A to SC, a channel layer 123 may be isolated by a second isolation structure 147. First isolation structures 146 may be in contact with the second isolation structure 147. A memory layer 121 may be isolated by the first isolation structure 146,

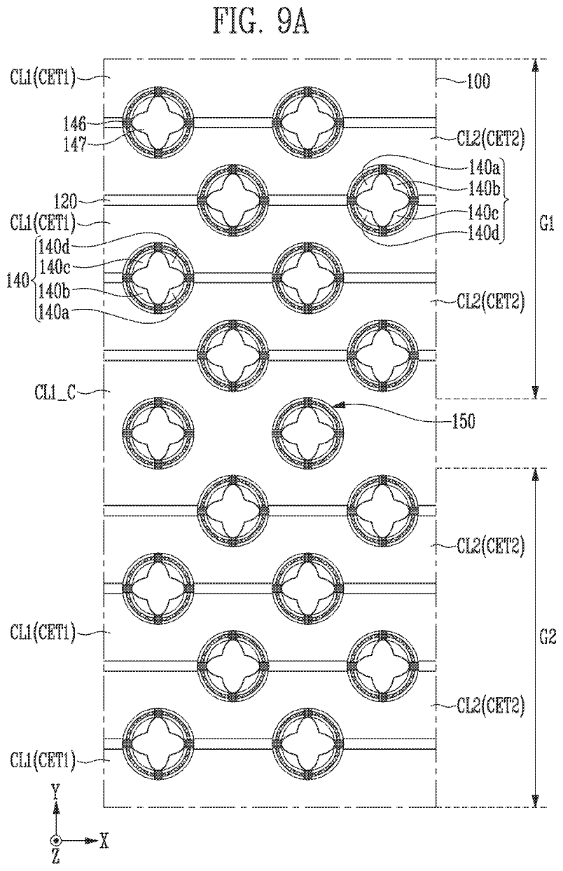

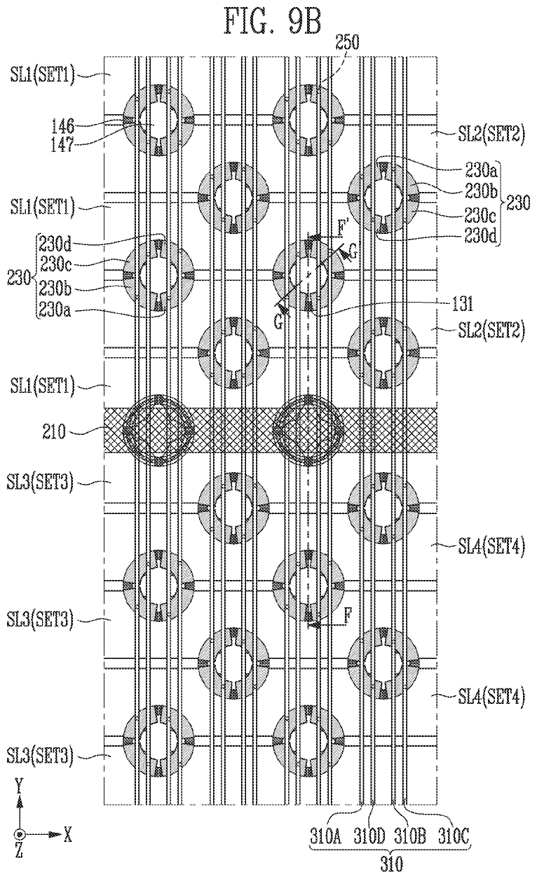

FIGS. 9A and 9B are plan views illustrating a layout of a semiconductor memory device in accordance with another embodiment of the present disclosure.

The semiconductor memory device in accordance with this embodiment of the present disclosure may be similar to the semiconductor memory device shown in FIGS. 3A and 3B, except portions described below.

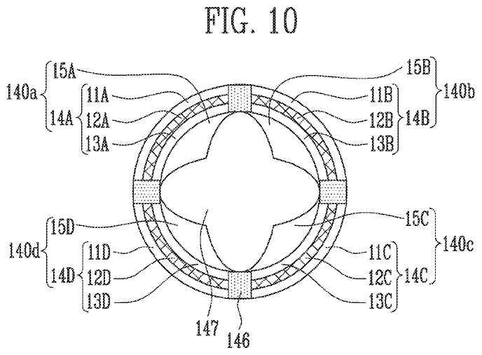

Referring to FIGS. 9A and 9B, each vertical structure 140 may include a first vertical structure 140a, a second vertical structure 140b, a third vertical structure 140c, and a fourth vertical structure 140d. Side portions of the first vertical structure 140a and the second vertical structure 140b may be in contact with a second cell line part CL2 corresponding thereto and a second select line part SL2 corresponding thereto. Side portions of the third vertical structure 140c and the fourth vertical structure 140d may be in contact with a first cell line part CL1 corresponding thereto and a first select line part SL1 corresponding thereto. The first vertical structure 140a, the second vertical structure 140b, the third vertical structure 140c, and the fourth vertical structure 140d may be isolated from each other by a first isolation structure 146 and a second isolation structure 147. A detailed structure of the vertical structure 140 will be described later with reference to FIG. 10.

The vertical structures 140 may be connected to bit lines 310. The bit lines 310 may be disposed to be spaced apart from first to fourth select stack structures SET1 to SET4 in the third direction Z, and be disposed above the first to fourth select stack structures SET1 to SET4. The bit lines 310 may be arranged to be spaced apart from each other in the first direction X. The bit lines 310 may extend in the second direction.

The bit lines 310 may be electrically connected to the vertical structures 140 through bit line contact structures 230a, 230b, 230c, and 230d. The bit lines 310 may include a conductive material. For example, the bit lines 310 may include tungsten, aluminum or copper.

The bit line contact structures 230a, 230b, 230c, and 230d may include a first bit line contact structure 230a on the first vertical structure 140a, a second bit line contact structure 230b on the second vertical structure 140b, a third bit line contact structure 230c on the third vertical structure 140c, and a fourth bit line contact structure 230d on the fourth vertical structure 140d. The bit lines 310 may include first to fourth bit lines 310A to 310D overlapping with the first to fourth vertical structures 140a to 140d facing each other. The first to fourth bit lines 310A to 310D may be spaced apart from the first to fourth bit line contact structures 230a to 230d in the third direction Z. Each of the first to fourth vertical structures 140a to 140d may be connected to a bit line 310 corresponding thereto by an upper contact 250. In one embodiment, the first vertical structure 140a may be connected to the first bit line 310A through an upper contact 250 disposed between the first bit line contact structure 230a and the first bit line 310A at an intersection portion of the first bit line contact structure 230a and the first bit line 310A. The second vertical structure 140b may be connected to the second bit line 3103 through an upper contact 250 disposed between the second bit line contact structure 230b and the second bit line 3103 at an intersection portion of the second bit line contact structure 230b and the second bit line 310B. The third vertical structure 140c may be connected to the third bit line 310C through an upper contact disposed between the third bit line contact structure 230c and the third bit line 310C at an intersection portion of the third bit line contact structure 230c and the third bit line 310C. The fourth vertical structure 140d may be connected to the fourth bit line 310D through an upper contact 250 disposed between the fourth bit line contact structure 230d and the fourth bit line 310D at an intersection portion of the fourth bit line contact structure 230d and the fourth bit line 310D,

FIG. 10 is a view illustrating a cross-section of a vertical structure in accordance with another embodiment of the present disclosure.

The vertical structure in accordance with this embodiment of the present disclosure may be similar to the vertical structure shown in FIG. 4, except portions described below.

Referring to FIG. 10, the vertical structure in accordance with this embodiment of the present disclosure may include channel layers 15A, 15B, 15C, and 15D, memory layers 14A, 14B, 14C, and 14D surrounding the channel layers 15A, 153, 15C, and 15D, and a first isolation structure 146 isolating the memory layers 14A, 14B, 14C, and 14D, and a second isolation structure 147 isolating the channel layers 15A, 15B, 15C, and 15D. The channel layers 15A, 15B, 15C, and 15D may have a cylindrical shape penetrating the first and second cell stack structures CET1 and CET2 and the first and second select stack structures SET1 and SET2, which are described with reference to FIGS. 2A and 2B.

The memory layers 14A, 14B, 14C, and 14D isolated by the first isolation structure 146 may be referred to as first to fourth memory layers 14A to 14D, The channel layers 15A, 153, 15C, and 15D isolated by the second isolation structure 147 may be referred to as first to fourth channel patterns 15A to 15D. In one embodiment, one vertical structure may include four first isolation structures 146, and include a second isolation structure 147 as a shape in which long ellipses in contact with the first isolation structures 146 overlap with each other. The shapes of the four first isolation structures 146 and the second isolation structure 147 are not limited to those shown in the drawing. The first memory layer 14A and the first channel pattern 15A may constitute the first vertical structure 140a shown in FIGS. 9A and 93, The second memory layer 143 and the second channel pattern 153 may constitute the second vertical structure 140b shown in FIGS. 9A and 9B. The third memory layer 14C and the third channel pattern 15C may constitute the third vertical structure 140c shown in FIGS. 9A and 93. The fourth memory layer 14D and the fourth channel pattern 15D may constitute the fourth vertical structure 140d shown in FIGS. 9A and 93.

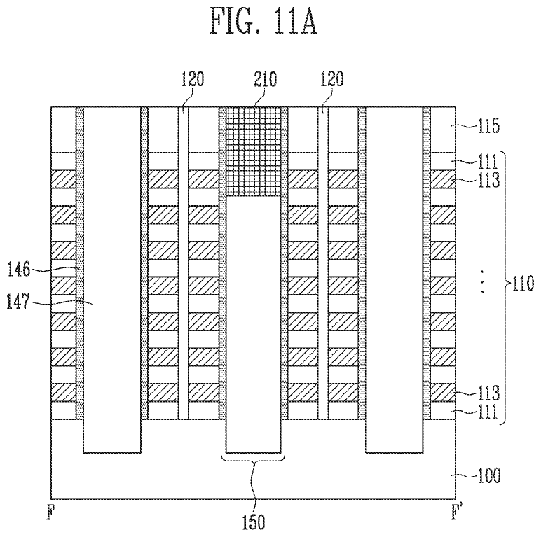

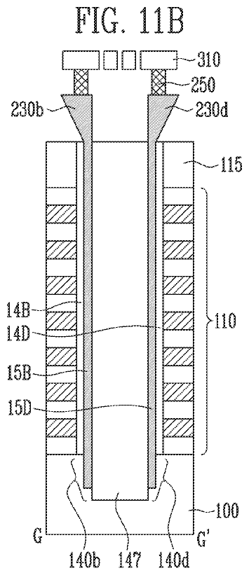

FIGS. 11A and 11B are sectional views of a semiconductor memory device taken along lines F-F′ and G-G′ shown in FIG. 93.

The semiconductor memory device in accordance with this embodiment of the present disclosure may be similar to the semiconductor memory device shown in FIGS. 5A and 53, except portions described below.

Referring to FIG. 11A, first isolation structure 146 may be in contact with a second isolation structure 147.

Referring to FIG. 113, a plurality of bit lines 310 may be disposed above one vertical stack structure. In one embodiment, when a channel layer is isolated into a first channel pattern 15A and a second channel pattern 153 by the second isolation structure 147, four bit lines 310 may be disposed above one vertical structure. The channel patterns may be controlled by the bit lines 310, respectively.

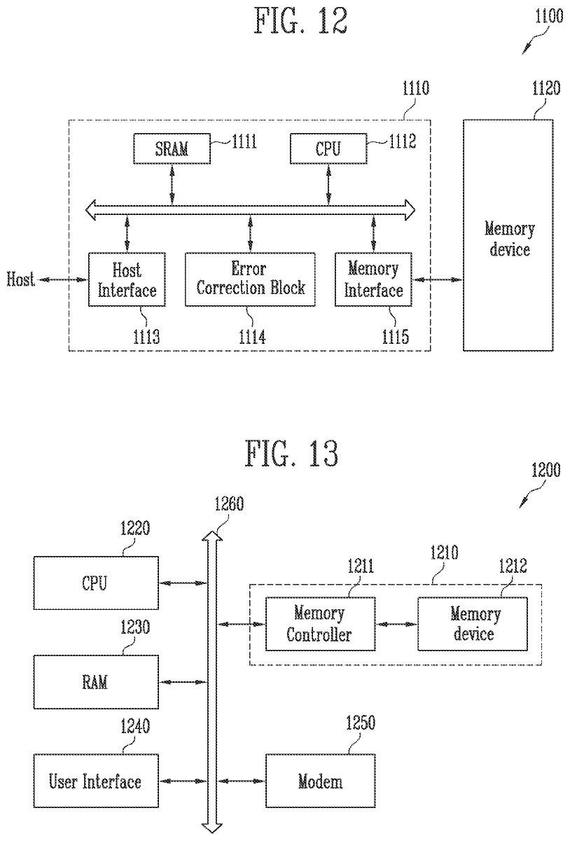

FIG. 12 is a block diagram illustrating a configuration of a memory system in accordance with another embodiment of the present disclosure.

Referring to FIG. 12, the memory system 1100 includes a memory device 1120 and a memory controller 1110.

The memory device 1120 may be a multi-chip package configured with a plurality of flash memory chips. The memory device 1120 may be a nonvolatile memory. Also, the memory device 1120 may have the structures described with reference to FIGS. 1 to 113. In one embodiment, the memory device 1120 may include: a first stack structure and a second stack structure on a semiconductor substrate; a first vertical structure having a sidewall in contact with the first stack structure, the first vertical structure including a first memory layer and a first channel pattern; a second vertical structure having a sidewall in contact with the second stack structure, the second vertical structure including a second memory layer and a second channel pattern; a first bit line contact structure on the first vertical structure; and a first bit line overlapping with the first bit line contact structure. Each of the first stack structure and the second stack structure may include conductive layers stacked on the semiconductor substrate to be spaced vertically apart from each other, and the first bit line contact structure may have a shape which is widened toward the first bit line. The structure of the memory device 1120 is identical to that described above, and therefore, its detailed descriptions will be omitted.

The memory controller 1110 controls the memory device 1120, and may include a Static Random Access Memory (SRAM) 1111, a Central Processing Unit (CPU) 1112, a host interface 1113, an error correction block 1114, and a memory interface 1115. The SRAM 1111 is used as an operation memory of the CPU 1112, the CPU 1112 performs overall control operations for data exchange of the memory controller 1110, and the host interface 1113 includes a data exchange protocol for a host connected with the memory system 1100, The error correction block 1114 detects an error included in a data read from the memory device 1120, and corrects the detected error. The memory interface 1115 interfaces with the memory device 1120. The memory controller 1110 may further include a Read Only Memory (ROM) for storing code data for interfacing with the host, and the like.

The memory system 1100 configured as described above may be a memory card or a Solid State Drive (SSD), in which the memory device 1120 is combined with the controller 1110, For example, when the memory system 1100 is an SSD, the memory controller 1100 may communicated with the outside (e.g., the host) through one of various interface protocols, such as a Universal Serial Bus (USB) protocol, a Multi-Media Card (MMC) protocol, a Peripheral Component Interconnection (PCI) protocol, a PCI-Express (PCI-e or PCIe) protocol, an Advanced Technology Attachment (ATA) protocol, a Serial-ATA (SATA) protocol, a Parallel-ATA (DATA) protocol, a Small Computer System Interface (SCSI) protocol, an Enhanced Small Disk Interface (ESDI) protocol, and an Integrated Drive Electronics (IDE) protocol,

FIG. 13 is a block diagram illustrating a configuration of a computing system in accordance with another embodiment of the present disclosure.

Referring to FIG. 13, the computing system 1200 may include a central processing unit (CPU) 1220, a random access memory (RAM) 1230, a user interface 1240, a modem 1250, and a memory system 1210, which are electrically connected to a system bus 1260. When the computing system 1200 is a mobile device, a battery for supplying an operation voltage to the computing system 1200 may be further included, and an application chip set, an image processor, a mobile D-RAM, and the like may be further included.

The memory system 1210 may be configured with a memory device 1212 and a memory controller 1211.

The memory controller 1211 may be configured identically to the memory controller 1110 described above with reference to FIG. 12.

In accordance with the present disclosure, vertical structures are isolated from each other, so that the degree of integration of memory cells can be improved.

In accordance with the present disclosure, since an isolation insulating layer is formed, a stack structure is isolated into two or more regions, so that the degree of integration of memory cells can be improved.

While the present disclosure has been shown and described with reference to certain exemplary embodiments thereof, it will be understood by those skilled in the art that various changes in form and details may be made therein without departing from the spirit and scope of the present disclosure as defined by the appended claims and their equivalents, Therefore, the scope of the present disclosure should not be limited to the above-described exemplary embodiments but also includes the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the exemplary embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A semiconductor memory device comprising:
a first stack structure and a second stack structure on a semiconductor substrate;
a first vertical structure having a sidewall in contact with the first stack structure, the first vertical structure including a first memory layer and a first channel pattern;
a second vertical structure having a sidewall in contact with the second stack structure, the second vertical structure including a second memory layer and a second channel pattern;
a first bit line contact structure on the first vertical structure; and
a first bit line overlapping with the first bit line contact structure,
wherein each of the first stack structure and the second stack structure includes conductive layers stacked on the semiconductor substrate to be spaced vertically apart from each other, and
wherein the first bit line contact structure has a shape which is widened toward the first bit line.

2. The semiconductor memory device of claim 1, wherein the first stack structure includes first conductive layers of the conductive layers stacked on the semiconductor substrate to be spaced vertically apart from each other, and
the second stack structure includes second conductive layers of the conductive layers stacked on the semiconductor substrate to be spaced vertically apart from each other, and
wherein the first conductive layers and the second conductive layers are disposed at the same level.

3. The semiconductor memory device of claim 1, further comprising an isolation insulating layer disposed between the first stack structure and the second stack structure.

4. The semiconductor memory device of claim 1, further comprising
a first isolation structure disposed between the first memory layer and the second memory layer; and
a second isolation structure disposed between the first channel pattern and the second channel pattern.

5. The semiconductor memory device of claim 1, wherein the first bit line contact structure extends from the first channel pattern to protrude beyond the first stack structure.

6. The semiconductor memory device of claim 1, further comprising an upper contact disposed between the first bit line contact structure and the first bit line.

7. The semiconductor memory device of claim 1, wherein the first stack structure includes a first cell stack structure and a first select stack structure, and
the second stack structure includes a second cell stack structure and a second select stack structure, and
wherein the semiconductor memory device further comprises an isolation structure disposed between the first select stack structure and the second select stack structure.

8. The semiconductor memory device of claim 7, further comprising a dummy vertical structure penetrating the first stack structure or the second stack structure.

9. The semiconductor memory device of claim 7, wherein the first stack structure includes first conductive layers of the conductive layers stacked on the semiconductor substrate to be spaced apart from each other, and
the second stack structure includes second conductive layers of the conductive layers stacked on the semiconductor substrate to be spaced apart from each other,
wherein two or more line isolation structures are provided, and
wherein a distance between the first conductive layers is smaller than a distance between the line isolation structures.

10. A semiconductor memory device comprising:
a first stack structure and a second stack structure on a semiconductor substrate;
a first vertical structure having a sidewall in contact with the first stack structure, the first vertical structure including a first memory layer and a first channel pattern;
a second vertical structure having a sidewall in contact with the first stack structure, the second vertical structure including a second memory layer and a second channel pattern;
a third vertical structure having a sidewall in contact with the second stack structure, the third vertical structure including a third memory layer and a third channel pattern;
a fourth vertical structure a sidewall in contact with the second stack structure, the fourth vertical structure including a fourth memory layer and a fourth channel pattern;
a first bit line contact structure on the first vertical structure; and
a first bit line overlapping with the first bit line contact structure,
wherein each of the first stack structure and the second stack structure includes conductive layers stacked on the semiconductor substrate to be spaced vertically apart from each other, and
wherein the first bit line contact structure has a shape which is widened toward the first bit line.

11. The semiconductor memory device of claim 10, further comprising an isolation insulating layer disposed between the first stack structure and the second stack structure.

12. The semiconductor memory device of claim 10, further comprising:
a first isolation structure disposed between the first memory layer and the second memory layer; and
a second isolation structure disposed between the first channel pattern and the second channel pattern.

13. The semiconductor memory device of claim 10, further comprising an upper contact disposed between the first bit line contact structure and the first bit line.

14. The semiconductor memory device of claim 10, wherein the first bit line contact structure extends from the first channel pattern to protrude beyond the first stack structure.

15. A semiconductor memory device comprising:
a first stack structure and a second stack structure on a semiconductor substrate;
a first vertical structure having a sidewall in contact with the first stack structure, the first vertical structure including a first memory layer and a first channel pattern extending vertically away from the semiconductor substrate;
a second vertical structure having a sidewall in contact with the second stack structure, the second vertical structure including a second memory layer and a second channel pattern extending vertically away from the semiconductor substrate;
a bit line contact structure on the first vertical structure; and
a bit line overlapping with the bit line contact structure,
wherein the first channel pattern is isolated into first separate channel patterns by vertically extending isolation layers disposed against the sidewall of the first vertical structure,
wherein the second channel pattern is isolated into second separate channel patterns by vertically extending isolation layers disposed against the sidewall of the second vertical structure, and
wherein the hit line contact structure contacts one of the first separate channel patterns.

16. The semiconductor memory device of claim 15, wherein the first memory layer is disposed on the sidewall of the first vertical structure and extends vertically away from the semiconductor substrate.

17. The semiconductor memory device of claim 16, wherein the first channel pattern and the first memory layer have a cylindrical shape penetrating the first cell stack structure.

18. The semiconductor memory device of claim 15, further comprising a first isolation structure contacting with the vertically extending isolation layers and overlapping with the first memory layer and the second memory layer.

19. The semiconductor memory device of claim 15, wherein each of the first stack structure and the second stack structure includes conductive layers stacked on the semiconductor substrate to be spaced vertically from each other.

20. The semiconductor memory device of claim 15, wherein the bit line contact structure has a shape which is widened toward the bit line.
